(19) United States
(12) Patent Application Publication
(10) Pub. No.: US 2026/0089946 A1
(43) Pub. Date: Mar. 26, 2026

(54) SEMICONDUCTOR DEVICE

(71) Applicant: SK hynix Inc., Icheon-si Gyeonggi-do (KR)

(72) Inventor: Doo Hoa CHOI, Icheon-si Gyeonggi-do (KR)

(73) Assignee: SK hynix Inc., Icheon-si Gyeonggi-do (KR)

(21) Appl. No.: 19/010,905

(22) Filed: Jan. 6, 2025

(30) Foreign Application Priority Data
Sep. 25, 2024 (KR) 10-2024-0130018

(51) Int. Cl. H10B 43/27; H10B 41/10; H10B 41/27; H10B 43/10

(52) U.S. Cl. CPC H10B 43/27; H10B 41/10; H10B 41/27; H10B 43/10

(57) ABSTRACT

A semiconductor device includes: a channel array including channel structures arranged in a first direction and a second direction intersecting the first direction; a first contact plug located to correspond to a center region of the channel array and spaced apart from the channel array by a first distance; and a second contact plug located to correspond to an edge region of the channel array and spaced apart from the channel array by a second distance smaller than the first distance.

### CROSS-REFERENCE TO RELATED APPLICATION

The present application claims priority under 35 U.S.C. § 119 (a) to Korean Patent Application No. 10-2024-0130018 filed in the Korean Intellectual Property Office on Sep. 25, 2024, which application is incorporated herein by reference in its entirety.

### BACKGROUND

### 1. Technical Field

Embodiments of the present disclosure generally relate to an electronic device, and more particularly, to a semiconductor device.

### 2. Related Art

The degree of integration of a semiconductor device is mainly determined by an area occupied by a unit memory cell. Recently, as the improvement in the degree of integration of a semiconductor device for forming memory cells in a single layer on a substrate reaches a limit, a three-dimensional semiconductor device for stacking memory cells on a substrate has been proposed. Furthermore, in order to improve the operational reliability of such a semiconductor device, various structures and manufacturing methods have been developed.

### SUMMARY

In an embodiment, a semiconductor device may include: a channel array including channel structures arranged in a first direction and a second direction intersecting the first direction; a first contact plug located to correspond to a center region of the channel array and spaced apart from the channel array by a first distance; and a second contact plug located to correspond to an edge region of the channel array and spaced apart from the channel array by a second distance smaller than the first distance.

In an embodiment, a semiconductor device may include: a stack; channel structures extending through the stack and arranged in a first direction and a second direction intersecting the first direction; and contact plugs extending through the stack and adjacent to the channel structures in the second direction, wherein the stack may include a cell region where the channel structures are located, a contact region where the contact plugs are located, and a buffer region located between the cell region and the contact region, and wherein a portion of the buffer region corresponding to a center region of the cell region may have a first width in the second direction, and a portion of the buffer region corresponding to a first edge region of the cell region may have a second width smaller than the first width in the second direction.

### BRIEF DESCRIPTION OF THE DRAWINGS

FIGS. 1A, 1B, and 1C are diagrams illustrating the structure of a semiconductor device in accordance with an embodiment.

FIGS. 2A and 2B are diagrams illustrating the structure of a semiconductor device in accordance with an embodiment.

FIGS. 3A, 3B, and 3C are diagrams illustrating the structure of a semiconductor device in accordance with an embodiment.

FIGS. 4A, 4B, and 4C are diagrams illustrating the structure of a semiconductor device in accordance with an embodiment.

FIG. 5 is a diagram illustrating the structure of a semiconductor device in accordance with an embodiment.

FIG. 6 is a diagram illustrating the structure of a semiconductor device in accordance with an embodiment.

### DETAILED DESCRIPTION

Various embodiments are directed to a semiconductor device having a stable structure and improved characteristics. It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present disclosure. These terms are only used to distinguish one element, component, region, layer or section from another element, component, region, layer or section, but not used to define only the element itself or to mean a particular sequence.

In an embodiment, by stacking memory cells in three dimensions, it is possible to improve the degree of integration of a semiconductor device. In an embodiment, it is also possible to provide a semiconductor device having a stable structure and improved reliability.

Hereafter, embodiments in accordance with the technical spirit of the present disclosure will be described with reference to the accompanying drawings.

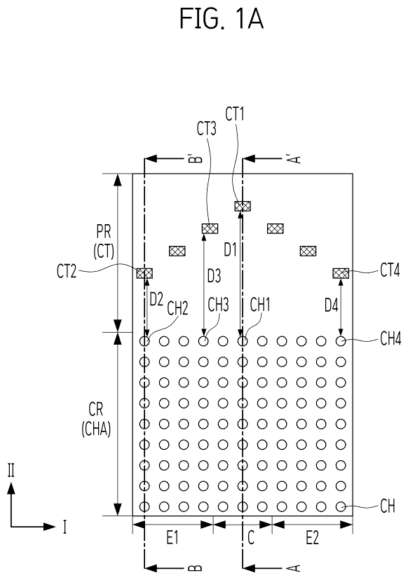

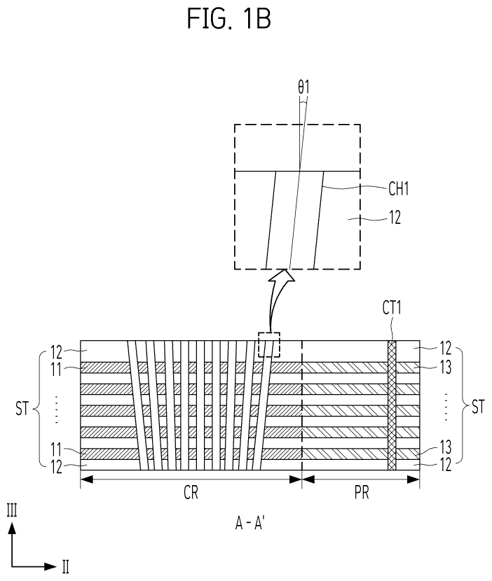

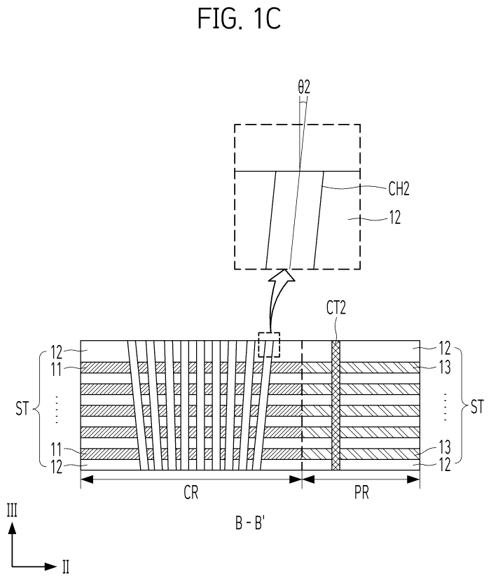

FIGS. 1A to 1C are diagrams illustrating the structure of a semiconductor device in accordance with an embodiment.

Referring to FIGS. 1A to 1C, the semiconductor device may include a channel array CHA and contact plugs CT, and may further include a stack ST. The stack ST may include a cell region CR and a peripheral region PR. The cell region CR may be a region where a cell array including stacked memory cells is located, and the peripheral region PR may be a region located around the cell region CR. As an example, the peripheral region PR may be a peripheral circuit region. The cell region CR and the peripheral region PR may be adjacent to each other in a second direction II.

The cell region CR of the stack ST may include conductive layers 11 and first insulating layers 12 that are alternately stacked. The peripheral region PR of the stack ST may include first insulating layers 12 and second insulating layers 13 that are alternately stacked. The cell region CR and the peripheral region PR may share the first insulating layers 12 with each other. The conductive layers 11 and the second insulating layers 13 may be located at levels corresponding to each other.

The channel array CHA may be located in the cell region CR (i.e., CR(CHA)) of the stack ST, and may include channel structures CH arranged in a first direction I and the second direction II intersecting the first direction I. The contact plugs CT may be located in the peripheral region PR (i.e., PR(CT)), and may be adjacent to the channel array CHA in the second direction II.

The channel structures CH may extend through the stack ST. The channel structures CH may penetrate through the stack ST in a third direction III. As an example, the third direction III may be a direction perpendicular to a plane defined by the first direction I and the second direction II. Extension angles of the channel structures CH may be different from each other depending on locations of the channel structures CH in the channel array CHA. The channel structures CH located at an edge of the channel array CHA may extend in an inclined state compared to the channel structures CH located at an inner portion of the channel array CHA.

Memory cells or select transistors may be located in regions where the channel structures CH and the conductive layers 11 intersect each other. Each of the channel structures CH may include a channel layer, a memory layer surrounding the channel layer, and an insulating core located in the channel layer. The channel layer may include a semiconductor material, such as silicon or germanium. The memory layer may include at least one of a tunneling layer, a data storage layer, and a blocking layer. The data storage layer may include a floating gate, polysilicon, a charge trap material, nitride, a variable resistance material, or the like.

A center region C and edge regions E1 and E2 of the channel array CHA may be defined along the first direction I. The center region C may be located between a first edge region E1 and a second edge region E2. A first channel structure CH1 may be located in the center region C, a second channel structure CH2 may be located in the first edge region E1, and a fourth channel structure CH4 may be located in the second edge region E2.

The contact plugs CT may extend through the stack ST. The contact plugs CT may penetrate through the stack in the third direction III. The contact plugs CT may be dummy contact plugs or real contact plugs connected to wiring lines. When the contact plugs CT are the dummy contact plugs, the contact plugs CT may have a state in which they are electrically floated. When the contact plugs CT are the real contact plugs, the contact plugs CT may electrically connect metal wiring lines disposed at a lower portion of the stack ST and metal wiring lines disposed at an upper portion of the stack ST to each other, and may be connected to a power source, such as VCC or VSS. The contact plugs CT may each include metal, such as tungsten.

The contact plugs CT may be located to correspond to the center region C or the edge regions E1 and E2. A first contact plug CT1 may be located to correspond to the center region C of the channel array CHA, a second contact plug CT2 may be located to correspond to the first edge region E1 of the channel array CHA, and a fourth contact plug CT4 may be located to correspond to the second edge region E2 of the channel array CHA. For example, the first contact plug CT1 may be inline with the center region C of the channel array in the second direction II as shown in FIG. 1A. For example, the second contact plug CT2 may be inline with the first edge region E1 of the channel array in the second direction II as shown in FIG. 1A. In an embodiment, the fourth contact plug CT4 may be inline with the second edge region E2 of the channel array CHA in the second direction II as shown in FIG. 1A. In an embodiment, the third contact plug CT3 may be located between the first contact plug CT1 and the second contact plug CT2 and inline with the first edge region E1, with the center region C, or with the boarder of the first edge region E1 and the center region C.

A penetration structure might not be located between the contact plugs CT and the channel array CHA. Here, the penetration structure may refer to a structure penetrating through the stack ST, such as the channel structure or the contact plug. The penetration structure might not be located between the center region C and the first contact plug CT1, between the first edge region E1 and the second contact plug CT2, or between the second edge region E2 and the fourth contact plug CT4.

Distances between the contact plugs CT1 to CT4 and the channel array CHA may be determined in consideration of a difference in gradient depending on the locations of the channel structures CH in the channel array CHA. Describing an arrangement of the channel array CHA, the channel structures CH are arranged in a matrix form of n×m. Accordingly, inclination directions and sizes of the channel structures CH may be different from each other depending on locations of the channel structures CH in a matrix. Among the channel structures CH arranged at the edge of the channel array CHA, a channel structure CH located at a corner of the edge may be inclined less than a channel structure CH located at the center of the edge. As an example, the second and fourth channel structures CH2 and CH4 respectively located in the edge regions E1 and E2 may be inclined less than the first channel structure CH1 located in the center region C. When gradients of the channel structures CH are different from each other, there may be a difficulty in measuring and correcting the gradients of the channel structures CH. As a height of the stack ST increases, a deviation between the gradients may increase, and there is a difficulty in correcting a shift of the channel structure CH.

According to an embodiment of the present disclosure, by locating the second and fourth contact plugs CT2 and CT4 that cause tensile stress to close to the channel array CHA, it is possible to increase the tensile stress applied to the second and fourth channel structures CH2 and CH4 from the second and fourth contact plugs CT2. In an embodiment, the tensile stress may occur as material layers shrink due to a heat treatment process performed in a manufacturing process.

The first contact plug CT1 may be spaced apart from the channel array CHA by a first distance D1. In an embodiment, the first distance D1 may be a distance between the first contact plug CT1 and the first channel structure CH1, and may be a sufficiently spaced distance so that tensile stress due to shrinkage of the first contact plug CT1 does not affect the first channel structure CH1. The second contact plug CT2 may be spaced apart from the channel array CHA by a second distance D2. In an embodiment, the second distance D2 may be a distance between the second contact plug CT2 and the second channel structure CH2, and may be a close distance so that tensile stress due to shrinkage of the second contact plug CT2 affects the second channel structure CH2. The fourth contact plug CT4 may be spaced apart from the channel array CHA by a fourth distance D4. In an embodiment, the fourth distance D4 may be a close distance so that tensile stress due to shrinkage of the fourth contact plug CT4 affects the fourth channel structure CH4. The second distance D2 and the fourth distance D4 may be smaller than the first distance D1. The second distance D2 and the fourth distance D4 may be substantially the same as each other.

In an embodiment, magnitudes of the tensile stress applied to the edge regions E1 and E2 by the second and fourth contact plugs CT2 and CT4 may be increased, and gradients of the second and fourth channel structures CH2 and CH4 may be increased. The first channel structure CH1 may be inclined toward the first contact plug CT1 by a first angle θ1, and the second channel structure CH2 may be inclined toward the second contact plug CT2 by a second angle θ2. In an embodiment, the first angle θ1 and the second angle θ2 may be substantially the same as each other.

For reference, a third channel structure CH3 may be located between the first channel structure CH1 and the second channel structure CH2, and a third contact plug CT3 may be located between the first contact plug CT1 and the second contact plug CT2. The third channel structure CH3 and the third contact plug CT3 may be spaced apart from each other by a third distance D3, and the third distance D3 may be smaller than the first distance D1 and greater than the second distance D2. A gradient of the third channel structure CH3 may be substantially the same as a gradient of the first channel structure CH1.

According to the structure described above, in an embodiment, the second and fourth contact plugs CT2 and CT4 may be located closer to the channel array CHA than the first contact plug CT1, and the first contact plug CT1 may be located further from the channel array CHA than the second and fourth contact plugs CT2 and CT4. Accordingly, in an embodiment, the gradient of the first channel structure CH1 located in the center region C and the gradients of the second and fourth channel structures CH2 and CH4 located in the edge regions E1 and E2 may become similar to each other.

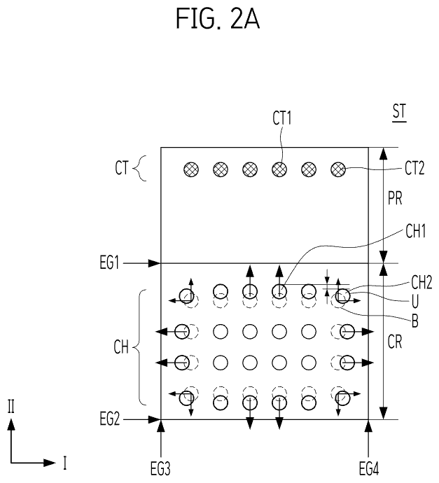

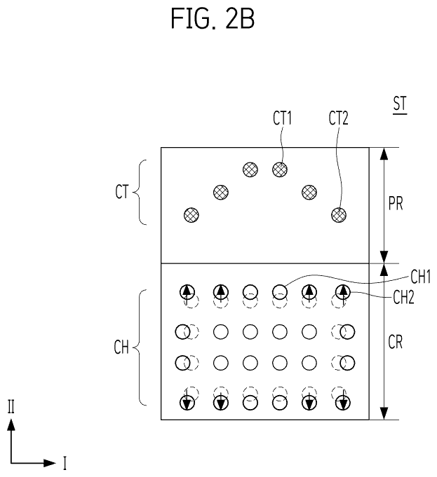

FIGS. 2A and 2B are diagrams illustrating the structure of a semiconductor device in accordance with an embodiment. Hereinafter, the content overlapping with the previously described content may be omitted.

Referring to FIG. 2A, the semiconductor device may include channel structures CH located in a cell region CR of a stack ST and contact plugs CT located in a peripheral region PR of the stack ST. The channel structures CH may be arranged in the first direction I and the second direction II, and may be arranged in a matrix form. The contact plugs CT may be spaced apart from the channel structures CH by a predetermined distance. The word “predetermined” as used herein with respect to a parameter, such as a predetermined distance, means that a value for the parameter is determined prior to the parameter being used in a process or algorithm. For some embodiments, the value for the parameter is determined before the process or algorithm begins. In other embodiments, the value for the parameter is determined during the process or algorithm but before the parameter is used in the process or algorithm.

In an embodiment, the channel structures CH may be exposed to stress in a manufacturing process. In the manufacturing process, in some embodiments, layers located in the peripheral region PR may shrink. As an example, an oxide layer and/or a nitride layer included in the stack ST may shrink or metal layers of the contact plugs CT may shrink. For this reason, in an embodiment, tensile stress may be caused, and the channel structures CH may be bent. The bent channel structures CH may be located with their upper surfaces U and lower surfaces B offset.

Degrees and directions where the channel structures CH are bent may be different from each other depending on locations of the channel structures CH in the cell region CR. The cell region CR may include a first edge EG1 extending in the first direction I and adjacent to the peripheral region PR and a second edge EG2 extending in the first direction I and spaced apart from the peripheral region PR. The cell region CR may include a third edge EG3 and a fourth edge EG4 that extend in the second direction II. A region defined by the first to fourth edges EG1 to EG4 may correspond to the channel array described above. The cell region CR may include at least one channel array.

Among the channel structures CH arranged in the matrix form, channel structures CH located at the edges EG1 to EG4 may be bent more than channel structures CH located inside. The channel structures CH located at the edges EG1 to EG4 may be inclined toward the outside of the edges EG1 to EG4. In an embodiment, tensile stress in the first direction I and/or the second direction II may be applied to the channel structures CH, and the channel structures CH may be inclined in the first direction I and/or the second direction II. As an example, the lower surfaces B of the channel structures CH may be maintained in the matrix form, and the upper surfaces U of the channel structures CH may shift in the first direction I and/or the second direction II.

In an embodiment, the channel structures CH arranged along the first edge EG1 adjacent to the peripheral region PR and extending in the first direction I may be inclined in the second direction II toward the peripheral region PR. In an embodiment, the channel structures CH arranged along the second edge EG2 spaced apart from the peripheral region PR and extending in the first direction I may be inclined in the second direction II to become distant from the peripheral region PR. In an embodiment, the channel structures CH arranged along the edges EG3 and EG4 extending in the second direction II may be inclined in the first direction I.

In an embodiment, a first channel structure CH1 located at the center of the first edge EG1 may be inclined in the second direction II due to stress in the second direction II. In an embodiment, a second channel structure CH2 located at a corner of the first edge EG1 may be exposed to stress in the first direction I and stress in the second direction II, and may be inclined in a diagonal direction intersecting the first direction I and the second direction II. In an embodiment, the first channel structure CH1 located at the center of the first edge EG1 is exposed to the stress in one direction, whereas the second channel structure CH2 located at the corner of the first edge EG1 may be exposed to the stress in two directions and may be inclined less than the first channel structure CH1.

FIG. 2B illustrates an embodiment in which a difference between gradients of the first and second channel structures CH1 and CH2 described in FIG. 2A is corrected. When the channel structures CH are inclined due to the stress, in an embodiment, misalignment may be caused in a subsequent process. In addition, in an embodiment, when the gradients of the channel structures CH are different from each other, offset degrees of the lower surfaces B and the upper surfaces U of the channel structures CH may be different from each other for each of the channel structures CH, and there may be a difficulty in measuring and correcting the offset degrees. Accordingly, in an embodiment, locations of the contact plugs CT may be adjusted so that the channel structures CH have a uniform gradient.

As described above with reference to FIG. 2A, the second channel structure CH2 located at the corner of the first edge EG1 may be inclined less than the first channel structure CH1 located at the center of the first edge EG1. Accordingly, in an embodiment, the stress applied to the second channel structure CH2 may be increased so that the second channel structure CH2 that is relatively less inclined may be further inclined as much as the first channel structure CH1. FIG. 2B illustrates an embodiment in which the gradient of the second channel structure CH2 is increased by selectively increasing the stress applied to the second channel structure CH2. Through this, in an embodiment, the gradients of the second channel structure CH2 and the first channel structure CH1 may become substantially the same as each other.

Referring to FIG. 2B, the stress applied to the first and second channel structures CH1 and CH2 may be adjusted according to locations of first and second contact plugs CT1 and CT2. In an embodiment, the first contact plug CT1 may be a contact plug located closest to the first channel structure CH1, and may be located to be sufficiently spaced apart from the first channel structure CH1 not to apply additional stress to the first channel structure CH1. In an embodiment, the second contact plug CT2 may be a contact plug located closest to the second channel structure CH2, and may be located close to the second channel structure CH2 to apply additional stress to the second channel structure CH2. In an embodiment, tensile stress due to shrinkage of the second contact plug CT2 may be applied to the second channel structure CH2, and the gradient of the second channel structure CH2 may increase to become substantially the same as the gradient of the first channel structure CH1.

According to the structure described above, in an embodiment, by adjusting the locations of the contact plugs CT, the gradient of the channel structure CH that is relatively less inclined may be increased to match that of the channel structure CH that is relatively more inclined. In an embodiment, the second contact plug CT2 may be located close to the second channel structure CH2 to increase the gradient of the second channel structure CH2 located at the corner of the first edge EG1. In such a case, in an embodiment, the channel structures CH arranged along the edge may have a uniform gradient regardless of the center and the corner, and offset degrees of the lower surfaces B and the upper surfaces U of the channel structures CH may become uniform. Accordingly, in an embodiment, a difficulty in measuring and correcting the shifts of the channel structures CH may be reduced.

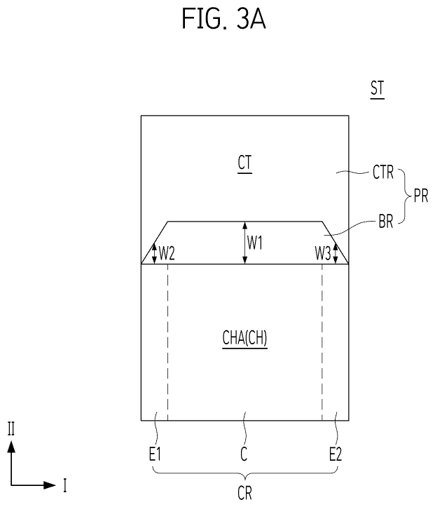

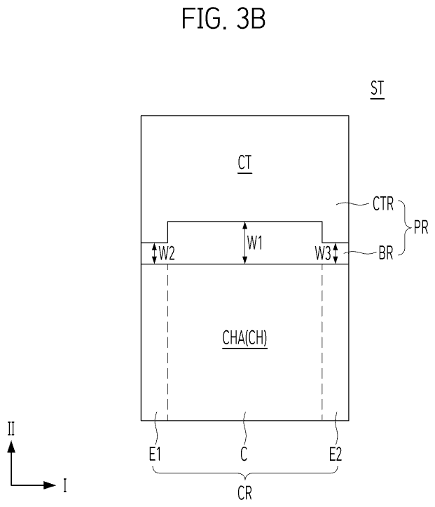

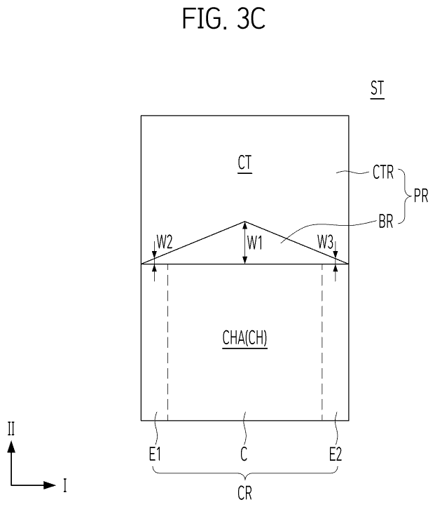

FIGS. 3A to 3C are diagrams illustrating the structure of a semiconductor device in accordance with an embodiment. Hereinafter, the content overlapping with the previously described content may be omitted.

Referring to FIGS. 3A to 3C, a stack ST may include a cell region CR and a peripheral region PR. The cell region CR and the peripheral region PR may be adjacent to each other in the second direction II. The cell region CR may be a region where a channel array CHA is located, and may be a region where channel structures CH arranged in the first direction I and the second direction II are located. The cell region CR may include a center region C, a first edge region E1, and a second edge region E2. The center region C may be located between the first edge region E1 and the second edge region E2 adjacent to each other in the first direction I.

The peripheral region PR may include a contact region CTR and a buffer region BR. The contact region CTR may be a region where contact plugs CT are located. The buffer region BR may be a region that does not include a penetration structure extending through the stack ST. The buffer region BR may be located between the contact region CTR and the cell region CR.

A portion of the buffer region BR corresponding to the center region C may have a first width W1. A portion of the buffer region BR corresponding to the first edge region E1 may have a second width W2, and the second width W2 may be smaller than the first width W1. A portion of the buffer region BR corresponding to the second edge region E2 may have a third width W3, and the third width W3 may be smaller than the first width W1. The second width W2 and the third width W3 may be substantially the same as or different from each other.

Referring to FIG. 3A, the buffer region BR may have a trapezoidal shape. A portion of the buffer region BR corresponding to the center region C may have a uniform width W1. Contact plugs CT arranged along an edge of the contact region CTR to correspond to the center region C may be located at substantially the same distance from the channel array CHA.

Portions of the buffer region BR corresponding to the first and second edge regions E1 and E2 may have widths that decrease as they become distant from the center region C. Contact plugs CT arranged along an edge of the contact region CTR to correspond to the first and second edge regions E1 and E2 may be located closer to the channel array CHA as they become distant from the center region C.

Referring to FIG. 3B, the buffer region BR may have a staircase shape. A portion of the buffer region BR corresponding to the center region C may have a uniform width W1. Contact plugs CT arranged along an edge of the contact region CTR to correspond to the center region C may be located at substantially the same distance from the channel array CHA.

A portion of the buffer region BR corresponding to the first edge region E1 may have a uniform width W2. Contact plugs CT arranged along an edge of the contact region CTR to correspond to the first edge region E1 may be located at substantially the same distance from the channel array CHA. A portion of the buffer region BR corresponding to the second edge region E2 may have a uniform width W3. Contact plugs CT arranged along an edge of the contact region CTR to correspond to the second edge region E2 may be located at substantially the same distance from the channel array CHA.

Referring to FIG. 3C, the buffer region BR may have a triangular shape. A portion of the buffer region BR corresponding to the center of the center region C may have a first width W1. A contact plug CT located to correspond to the center may be located to be spaced apart from the channel array CHA by a maximum distance.

Portions of the buffer region BR corresponding to the center region C and the edge regions E1 and E2 may have widths that decrease as they become distant from the center. Contact plugs CT arranged along an edge of the contact region CTR to correspond to the center region C and the edge regions E1 and E2 may be located closer to the channel array CHA as they become distant from the center.

According to the structure described above, the buffer region BR may be defined in various shapes. Distances between the channel array CHA and the contact plugs CT in the second direction II may be determined in consideration of a deviation between gradients of the channel structures CH according to an arrangement of the channel array CHA, and a shape of the buffer region BR may be determined according to locations of the contact plugs CT.

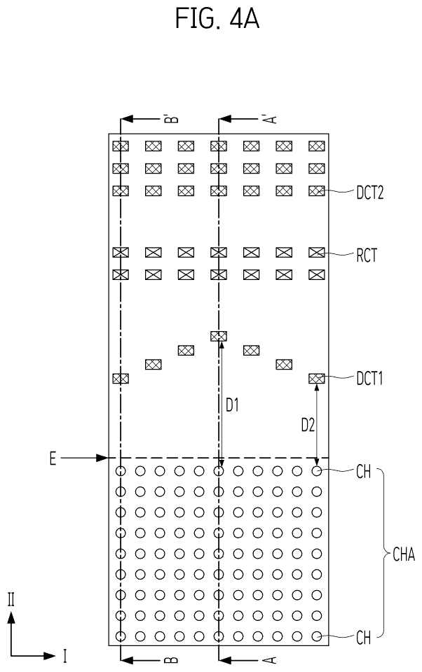

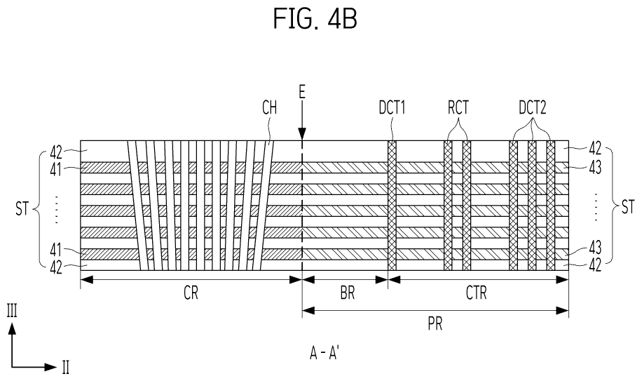

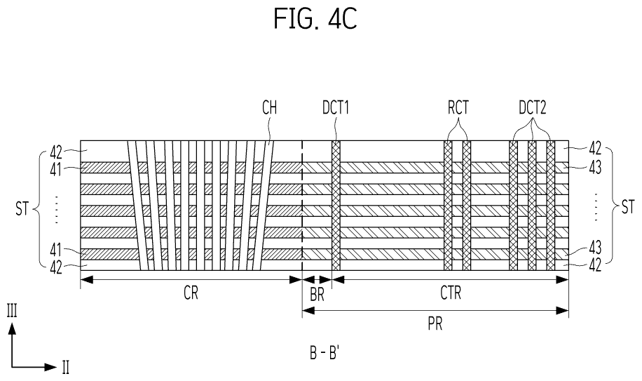

FIGS. 4A to 4C are diagrams illustrating the structure of a semiconductor device in accordance with an embodiment. Hereinafter, the content overlapping with the previously described content may be omitted.

Referring to FIGS. 4A to 4C, the semiconductor device may include a stack ST, a channel array CHA, first dummy contact plugs DCT1, real contact plugs RCT, and second dummy contact plugs DCT2. The channel array CHA may include channel structures CH arranged in the first direction I and the second direction II.

The stack ST may include a cell region CR and a peripheral region PR. The cell region CR of the stack ST may include conductive layers 41 and first insulating layers 42 that are alternately stacked. The peripheral region PR of the stack ST may include first insulating layers 42 and second insulating layers 43 that are alternately stacked. The peripheral region PR may include a buffer region BR and a contact region CTR. The buffer region BR may be located between the contact region CTR and the cell region CR.

The channel array CHA may be located in the cell region CR of the stack ST, and may include the channel structures CH arranged in the first direction I and the second direction II intersecting the first direction I. The first dummy contact plugs DCT1, the real contact plugs RCT, and the second dummy contact plugs DCT2 may be located in the contact region CTR of the peripheral region PR.

The channel structures CH may extend through the stack ST. The channel structures CH located at an edge of the channel array CHA may extend in an inclined state compared to the channel structures CH located at an inner portion of the channel array CHA.

The first and second dummy contact plugs DCT1 and DCT2 and the real contact plugs RCT may extend through the stack ST. The real contact plugs RCT may be electrically connected to wiring lines, and the first and second dummy contact plugs DCT1 and DCT2 may be in a state in which they are electrically floated. The real contact plugs RCT may be located between the first dummy contact plugs DCT1 and the second dummy contact plugs DCT2.

The buffer region BR may be defined between the first dummy contact plugs DCT1 and the channel array CHA, and a penetration structure might not be located in the buffer region BR. The buffer region BR may have a shape, such as a trapezoidal shape, a staircase shape or a triangular shape.

Channel structures CH arranged along an edge E of the cell region CR adjacent to the buffer region BR may be inclined toward the buffer region BR. A gradient of a channel structure CH located at the center of the edge E and a gradient of a channel structure CH located at a corner of the edge E may be substantially the same as each other. A distance between the channel structure CH located at the center of the edge E and the first dummy contact plug DCT1 may be a first distance D1. A distance between the channel structure CH located at the corner of the edge E and the first dummy contact plug DCT1 may be a second distance D2. Here, the second distance D2 may be smaller than the first distance D1, and through this, the gradient of the channel structure CH located at the corner of the edge E may be corrected.

According to the structure described above, the first dummy contact plug DCT1 located to correspond to the center of the edge E may be located distant from the channel structure CH, and the first dummy contact plug DCT1 located corresponding to the corner of the edge E may be located close to the channel structure CH. Accordingly, the gradients of the channel structures CH arranged along the edge E may become substantially the same as each other.

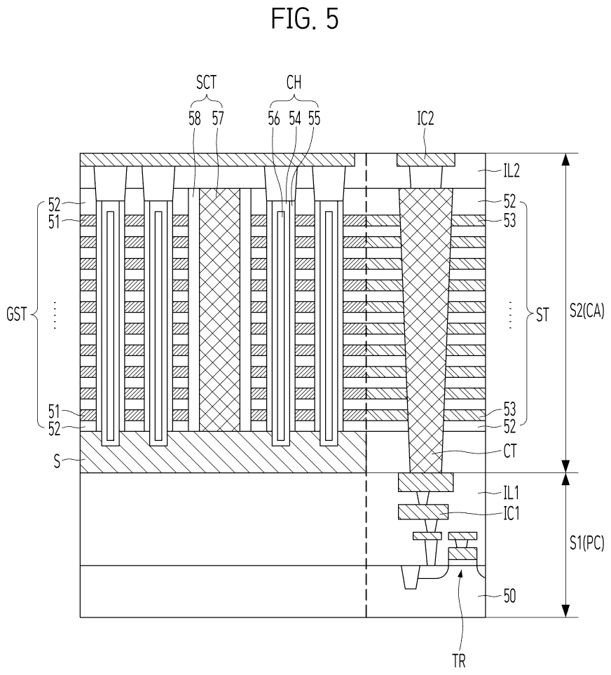

FIG. 5 is a diagram illustrating the structure of a semiconductor device in accordance with an embodiment. Hereinafter, the content overlapping with the previously described content may be omitted.

Referring to FIG. 5, the semiconductor device may include a first semiconductor structure S1 and a second semiconductor structure S2. The second semiconductor structure S2 may be located above the first semiconductor structure S1 or the first semiconductor structure S1 may be located above the second semiconductor structure S2.

The first semiconductor structure S1 may include a peripheral circuit PC. The peripheral circuit PC may include a row decoder, a page buffer, an input/output circuit, a logic circuit, and the like. As an example, the first semiconductor structure S1 may include a substrate 50, a transistor TR, a first interconnection structure IC1, and a first interlayer insulating layer IL1. The transistor TR may belong to the peripheral circuit PC. The first interconnection structure IC1 may be electrically connected to the peripheral circuit PC, and may be located in the first interlayer insulating layer IL1. The first interconnection structure IC1 may include a via, a wiring line, and the like.

The second semiconductor structure S2 may include a memory cell array CA including stacked memory cells. As an example, the second semiconductor structure S2 may include a source structure S, a gate structure GST, a stack ST, a channel structure CH, a contact plug CT, a source contact structure SCT, a second interconnection structure IC2, and a second interlayer insulating layer IL2.

The gate structure GST may be located on the source structure S. The gate structure GST may include conductive layers 51 and first insulating layers 52 that are alternately stacked. The channel structure CH may extend into the source structure S through the gate structure GST. The channel structure CH may include a channel layer 54, a memory layer 55, and an insulating core 56. The source contact structure SCT may include a source contact 57 electrically connected to the source structure S and an insulating spacer 58 surrounding a sidewall of the source contact 57.

The stack ST may include first insulating layers 52 and second insulating layers 53 that are alternately stacked. The contact plug CT may extend through the stack ST, and may penetrate through the stack ST.

The second interconnection structure IC2 may be electrically connected to the memory cell array CA, and may be located in the second interlayer insulating layer IL2. The second interconnection structure IC2 may include a via, a wiring line, and the like. As an example, the second interconnection structure IC2 may be connected to the contact plug CT, and the first interconnection structure IC1 and the second interconnection structure IC2 may be electrically connected to each other through the contact plug CT.

According to the structure described above, by stacking the first semiconductor structure S1 and the second semiconductor structure S2, it is possible to increase the degree of integration of the semiconductor device. By adjusting a distance between the channel structure CH and the contact plug CT, the channel structures CH arranged along an edge may have a uniform gradient.

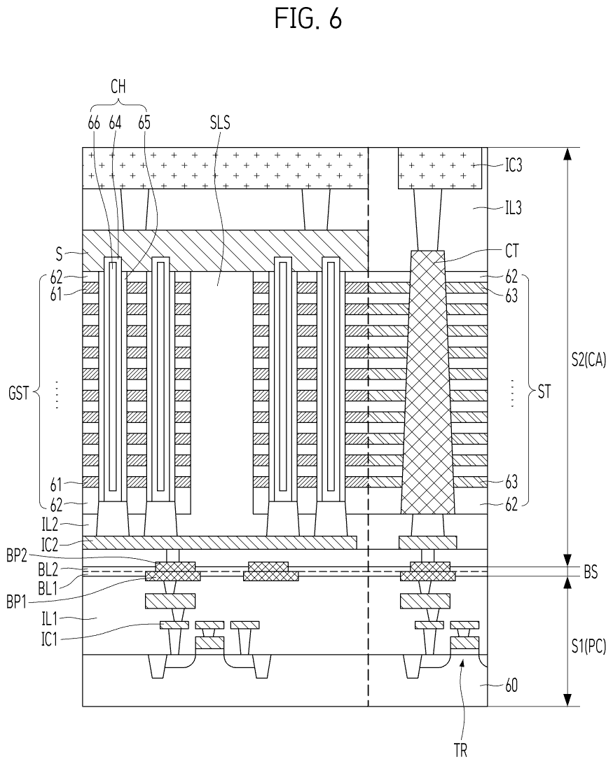

FIG. 6 is a diagram illustrating the structure of a semiconductor device in accordance with an embodiment. Hereinafter, the content overlapping with the previously described content may be omitted.

Referring to FIG. 6, the semiconductor device may include a first semiconductor structure S1, a second semiconductor structure S2, and a bonding structure BS. The first semiconductor structure S1 may include a peripheral circuit PC, and the second semiconductor structure S2 may include a memory cell array CA.

The first semiconductor structure S1 may include a substrate 60, a transistor TR, a first interlayer insulating layer IL1, and a first interconnection structure IC1. The transistor TR may belong to the peripheral circuit PC. The first interconnection structure IC1 may be located in the first interlayer insulating layer IL1, and may include a via, a wiring line, and the like. The first interconnection structure IC1 may be electrically connected to the peripheral circuit PC.

The second semiconductor structure S2 may include a source structure S, a gate structure GST, a stack ST, a channel structure CH, a slit structure SLS, a contact plug CT, a second interlayer insulating layer IL2, a second interconnection structure IC2, a third interlayer insulating layer IL3, and a third interconnection structure IC3.

The gate structure GST may include conductive layers 61 and first insulating layers 62 that are alternately stacked. The source structure S may be located above the gate structure GST. The channel structure CH may extend into the source structure S through the gate structure GST. The channel structure CH may include a channel layer 64, a memory layer 65, and an insulating core 66. The slit structure SLS may extend into the source structure S through the gate structure GST. The slit structure SLS may include an insulating material, a semiconductor material, and/or a conductive material.

The stack ST may include first insulating layers 62 and second insulating layers 63 that are alternately stacked. The contact plug CT may extend through the stack ST, and may penetrate through the stack ST.

The second interconnection structure IC2 may be located below the gate structure GST and the stack ST. The second interconnection structure IC2 may be electrically connected to the memory cell array CA, and may be located in the second interlayer insulating layer IL2. The second interconnection structure IC2 may include a via, a wiring line, and the like.

The third interconnection structure IC3 may be located above the gate structure GST and the stack ST. The third interconnection structure IC3 may be electrically connected to the memory cell array CA, and may be located in the third interlayer insulating layer IL3. The third interconnection structure IC3 may include a via, a wiring line, and the like.

The bonding structure BS may be located between the first semiconductor structure S1 and the second semiconductor structure S2. The first semiconductor structure S1 and the second semiconductor structure S2 may be manufactured separately, and may be electrically connected to each other by the bonding structure BS. The memory cell array CA including the gate structure GST and the peripheral circuit PC may be electrically connected to each other by the bonding structure BS.

The bonding structure BS may include a first bonding layer BL1, a second bonding layer BL2, a first bonding pad BP1, and a second bonding pad BP2. The first bonding layer BL1 and the second bonding layer BL2 may be in contact with each other, and the first bonding pad BP1 and the second bonding pad BP2 may be in contact with each other. The first bonding layer BL1 and the second bonding layer BL2 may each include SiCN, tetra ethyl ortho silicate (TEOS), or the like. The first bonding pad BP1 may be electrically connected to the first interconnection structure IC1, and the second bonding pad BP2 may be electrically connected to the second interconnection structure IC2. The memory cell array CA and the peripheral circuit PC may be electrically connected to each other through the first bonding pad BP1 and the second bonding pad BP2.

According to the structure described above, the first semiconductor structure S1 and the second semiconductor structure S2 are bonded to each other, and it is thus possible to increase the degree of integration of the semiconductor device. By adjusting a distance between the channel structure CH and the contact plug CT, the channel structures CH arranged along an edge may have a uniform gradient.

Although embodiments according to the technical idea of the present disclosure have been described above with reference to the accompanying drawings, this is only for explaining the embodiments according to the concept of the present disclosure, and the present disclosure is not limited to the above embodiments. Various types of substitutions, modifications, changes, and combinations for the embodiments may be made by those skilled in the art, to which the present disclosure pertains, without departing from the technical idea of the present disclosure defined in the following claims, and it should be construed that these substitutions, modifications, changes, and combinations belong to the scope of the present disclosure.

What is claimed is:

1. A semiconductor device comprising:
a channel array including channel structures arranged in a first direction and a second direction intersecting the first direction;
a first contact plug located inline with a center region of the channel array and spaced apart from the channel array by a first distance; and
a second contact plug located inline with an edge region of the channel array and spaced apart from the channel array by a second distance smaller than the first distance.

2. The semiconductor device of claim 1,
wherein a penetration structure is not located between the center region of the channel array and the first contact plug, and
wherein the penetration structure is not located between the edge region of the channel array and the second contact plug.

3. The semiconductor device of claim 1,
wherein a first channel structure located in the center region among the channel structures is inclined toward the first contact plug by a first angle, and
wherein a second channel structure located in the edge region among the channel structures is inclined toward the second contact plug by a second angle.

4. The semiconductor device of claim 3, wherein the second angle is substantially the same as the first angle.

5. The semiconductor device of claim 1, further comprising a third contact plug located between the first contact plug and the second contact plug,
wherein the channel structures include a first channel structure located in the center region, a second channel structure located in the edge region and a third channel structure located between the first channel structure and the second channel structure,
wherein the third channel structure is spaced apart from the third contact plug by a third distance, and
the third distance is greater than the second distance and less than the first distance.

6. The semiconductor device of claim 1, wherein the second contact plug includes tungsten.

7. The semiconductor device of claim 1, wherein the second contact plug is electrically connected to a wiring line.

8. The semiconductor device of claim 1, wherein the second contact plug is a dummy contact plug.

9. A semiconductor device comprising:
a stack;
channel structures extending through the stack and arranged in a first direction and a second direction intersecting the first direction; and
contact plugs extending through the stack and adjacent to the channel structures in the second direction,
wherein the stack includes a cell region where the channel structures are located, a contact region where the contact plugs are located, and a buffer region located between the cell region and the contact region, and
wherein a portion of the buffer region corresponding to a center region of the cell region has a first width in the second direction, and a portion of the buffer region corresponding to a first edge region of the cell region has a second width smaller than the first width in the second direction.

10. The semiconductor device of claim 9, wherein the buffer region does not include a penetration structure extending through the stack.

11. The semiconductor device of claim 9, wherein the buffer region has substantially a trapezoidal shape.

12. The semiconductor device of claim 9, wherein the cell region of the stack includes conductive layers and insulating layers that are alternately stacked.

13. The semiconductor device of claim 9, wherein the contact region and the buffer region of the stack include first insulating layers and second insulating layers that are alternately stacked.

14. The semiconductor device of claim 9,
wherein the cell region includes an edge adjacent to the buffer region and extending along the first direction, and
wherein channel structures arranged along the edge are inclined toward the buffer region.

15. The semiconductor device of claim 14, wherein the channel structures arranged along the edge are inclined at substantially the same angle.

16. The semiconductor device of claim 9, wherein the center region and the first edge region are adjacent to each other in the first direction.

17. The semiconductor device of claim 16, wherein the cell region includes the first edge region, a second edge region, and the center region located between the first edge region and the second edge region.

18. The semiconductor device of claim 17, wherein a portion of the buffer region inline with the second edge region has a third width smaller than the first width in the second direction.

19. The semiconductor device of claim 18, wherein the second width and the third width are substantially the same as each other.
